(19) United States
(12) Patent Application Publication
(10) Pub. No.: US 2025/0096724 A1
(43) Pub. Date: Mar. 20, 2025

(54) COVER PLATE ASSEMBLY AND FOLDABLE COVER PLATE

(71) Applicant: Shenzhen WKSP Power Technology Co., Ltd., Shenzhen City (CN)

(72) Inventors: Houwei HUANG, Shenzhen City (CN); Shengwen HONG, Shenzhen City (CN); Xiaohong YANG, Shenzhen City (CN); Qu ZHANG, Shenzhen City (CN); Yaping XU, Shenzhen City (CN)

(73) Assignee: Shenzhen WKSP Power Technology Co., Ltd., Shenzhen City (CN)

(21) Appl. No.: 18/431,409

(22) Filed: Feb. 2, 2024

(30) Foreign Application Priority Data
Sep. 14, 2023 (CN) 202311193224.4

(51) Int. Cl. H02S 30/10; B60J 7/14; B60R 16/03; H02S 30/20

(52) U.S. Cl. CPC H02S 30/10; B60R 16/03; H02S 30/20; B60J 7/141

(57) ABSTRACT

The present disclosure provides a cover plate assembly and a foldable cover plate. The cover plate assembly includes a photovoltaic panel, a bonding layer and a cover plate. The photovoltaic panel includes a light absorbing surface and a backlight surface opposite to the light absorbing surface. The bonding layer is bonded to the backlight surface. The cover plate is bonded to one side of the bonding layer away from the photovoltaic panel. The cover plate includes a supporting layer and a reinforcement layer. The reinforcement layer is located on at least one side of the supporting layer. The supporting layer includes a supporting layer or an aluminium alloy supporting layer.

### CROSS-REFERENCE TO RELATED APPLICATION

This application claims priority to and the benefit of Chinese Application Patent Application No. 202311193224.4, filed Sep. 14, 2023, the entire disclosure of which is hereby incorporated by reference.

### TECHNICAL FIELD

The present disclosure relates to a technical field of photovoltaic technology, and in particular relates to a cover plate assembly and a foldable cover plate.

### BACKGROUND

In the photovoltaic industry, photovoltaic panels are usually fixed with a supportive fixing structure made of ferro alloy or ferroalloy profile, which results in excess weight of the product, high manufacturing costs, not conducive to the transportation and installation of the product, and not insulated so it absorb heat easily.

### SUMMARY

In view of this, a first aspect of the present disclosure provides a cover plate assembly. The cover plate assembly includes a photovoltaic panel, a bonding layer, and a cover plate. The photovoltaic panel includes a light absorbing surface and a backlight surface opposite to the light absorbing surface. The bonding layer is bonded to the backlight surface. The cover plate is bonded to one side of the bonding layer away from the photovoltaic panel. The cover plate includes a supporting layer and a reinforcement layer. The reinforcement layer is located on at least one side of the supporting layer. The supporting layer includes a supporting layer or an aluminium alloy supporting layer.

In the cover plate assembly provided in the first aspect of the present disclosure, the backlight surface of the photovoltaic panel is bonded to the cover plate by the bonding layer, the cover plate serves as the supportive fixing structure of the photovoltaic panel. Moreover, the cover plate includes the supporting layer, the supporting layer includes a supporting layer or an aluminium alloy supporting layer, compared to the supportive fixing structure made of ferroalloy, the supporting layer made of plastic or aluminum alloy can reduce a weight of the photovoltaic panel component. In addition, the cover plate also includes the reinforcement layer, and using the reinforcement layer can improve a structural strength of the cover plate and better support the photovoltaic panel.

In summary, under a premise of supporting the photovoltaic panel, the cover plate provided in the present disclosure can reduce the weight of photovoltaic panel component, realize light weight of the product, reduce manufacturing, installation and transportation costs, and have good thermal insulation without absorbing heat.

The supporting layer includes a plurality of annular supporting portions connected with each other. Each annular supporting portion defines a through hole penetrating along a direction from the light absorbing surface to the backlight surface, an aperture of the through hole is 5 mm to 15 mm.

The cover plate further includes a heat insulation layer located between the supporting layer and the reinforcement layer.

The number of the reinforcement layer and the heat insulation layer are both two. The two reinforcement layers are located on opposite sides of the supporting layer. Each heat insulation layer is located between the supporting layer and the reinforcement layer.

A thickness of the reinforcement layer which is close to the photovoltaic panel is less than that of the reinforcement layer which is away from the photovoltaic panel.

The number of the photovoltaic panels is multiple. Multiple photovoltaic panels are bonded to the cover plate in an array by the bonding layer. The cover plate assembly further includes a flat layer. The flat layer is located on the cover plate where the photovoltaic panel is not set, and on the photovoltaic panel. A surface of the flat layer away from the cover plate is flush.

The cover plate assembly further includes a first electrical connecting member and a connector. The connector is fixed to one side of the cover plate away from the photovoltaic panel and directly faces the photovoltaic panel. One end of the first electrical connecting member is electrically connected to the photovoltaic panel and the other end of the first electrical connecting member passes through the bonding layer and the cover plate so as to be electrically connected to the connector.

The number of the cover plate assemblies is multiple. Multiple cover plate assemblies are rotationally connected in sequence along a predetermined direction. The connectors of the multiple cover plate assemblies are also arranged along the predetermined direction. The connector includes a positive terminal and a negative terminal. When the multiple cover plate assemblies are flattened, the positive terminal of each connector directly corresponds to the positive terminals of the other connectors, and the negative terminal of each connector directly corresponds to the negative terminals of the other connectors.

The cover plate assembly further includes at least one second electrical connecting member and at least one third electrical connecting member. Opposite ends of each second electrical connecting member are electrically connected to the positive terminals of the two adjacent connectors. Opposite ends of each third electrical connecting member are electrically connected to the negative terminals of the two adjacent connectors.

The second electrical connecting member and the third electrical connecting member are removably connected to the connector, and/or, the second electrical connecting member and the third electrical connecting member are capable of elongating in length and restored to their original shape.

A second aspect of the present disclosure provides a foldable cover plate for mounting to a tail box of a mobile device to cover an opening of the tail box. The foldable cover plate includes a plurality of cover plate assemblies rotationally connected as provided in the first aspect of the present disclosure and, and a profile. The cover plate assembly is rotatably foldable to the remaining cover plate assemblies to expose the opening. The profile defines a receiving groove. A peripheral edge of the cover plate assembly is bonded to a groove wall of the receiving groove.

The foldable cover plate provided in the second aspect of the present disclosure, by employing the cover plate assembly provided in the first aspect of the present disclosure, not only covers the opening of the tail box, but also utilizes the photovoltaic panel in the cover plate assembly to convert light energy into electrical energy, thereby providing electrical energy for the mobile device.

### BRIEF DESCRIPTION OF THE ACCOMPANYING DRAWINGS

In order to more clearly illustrate the technical solutions of the embodiments of the present disclosure, the accompanying drawings to be used in the embodiments will be briefly introduced below.

FIG. 1 illustrates a schematic structural view of a cover plate assembly in accordance with one embodiment of the present disclosure.

FIG. 2 illustrates an exploded view of the cover plate assembly in FIG. 1.

FIG. 3 illustrates a cross-sectional view of the cover plate assembly in FIG. 1.

FIG. 4 illustrates a schematic structural view of a supporting layer in accordance with a second embodiment of the present disclosure.

FIG. 5 illustrates a partial top view of the supporting layer in FIG. 4.

FIG. 6 illustrates a cross-sectional view of the cover plate assembly in accordance with a third embodiment of the present disclosure.

FIG. 7 illustrates a cross-sectional view of the cover plate assembly in accordance with a fourth embodiment of the present disclosure.

FIG. 8 illustrates a cross-sectional view of the cover plate assembly in accordance with a fifth embodiment of the present disclosure.

FIG. 9 illustrates a cross-sectional view of the cover plate assembly in accordance with a sixth embodiment of the present disclosure.

FIG. 10 illustrates a top view of the cover plate assembly in accordance with another embodiment of the present disclosure from another view.

FIG. 11 illustrates a cross-sectional view of the cover plate assembly in accordance with a seventh embodiment of the present disclosure.

FIG. 12 illustrates a schematic view of a fit of the foldable cover plate applied to a mobile device in accordance with one embodiment of the present disclosure.

FIG. 13 illustrates a schematic structural view of the foldable cover plate in accordance with one embodiment of the present disclosure.

FIG. 14 illustrates a schematic structural view of the foldable cover plate in FIG. 13 from another view.

FIG. 15 illustrates a schematic structural view of the foldable cover plate of FIG. 13 after being folded first time.

FIG. 16 illustrates a schematic structural view of the foldable cover plate of FIG. 13 after being folded second time.

FIG. 17 illustrates a partial cross-sectional view of the foldable cover plate of FIG. 13.

### LABELS OF DRAWINGS

1—cover plate assembly; 2—foldable cover plate; 3—mobile device; 10—cover plate; 110—supporting layer; 111—annular supporting portion; 112—through hole; 120—reinforcement layer; 130—heat insulation layer; 20—bonding layer; 30—photovoltaic panel; 301—light absorbing surface; 302—backlight surface; 310—battery sheet; 320—hot melt adhesive layer; 40—flat layer; 50—connector; 51—positive terminal; 52—negative terminal; 61—first electrical connecting member; 62—second electrical connecting member; 63—third electrical connecting member; 70—profile; 71—receiving groove; 81—driver's cab; 82—tail box.

### DETAILED DESCRIPTION OF ILLUSTRATED EMBODIMENTS

The following are preferred embodiments of the present disclosure, and it should be noted that for a person of ordinary skill in the art, a number of improvements and embellishments may be made without departing from the principles of the present disclosure, which are also regarded as the scope of protection of the present disclosure.

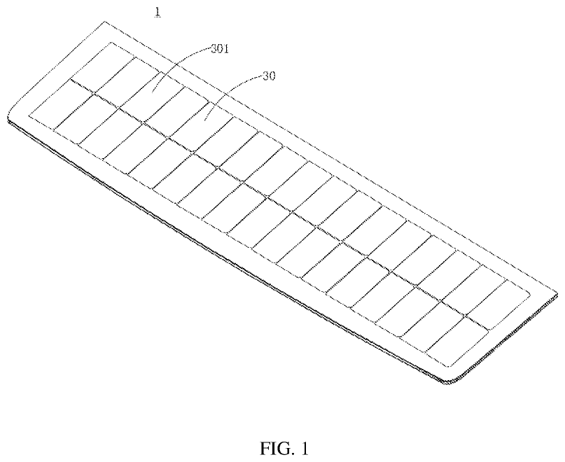

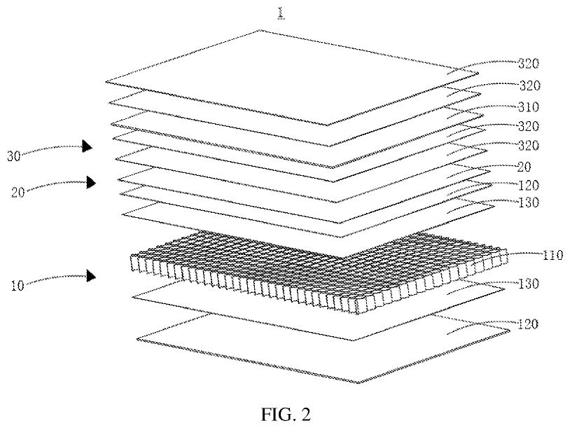

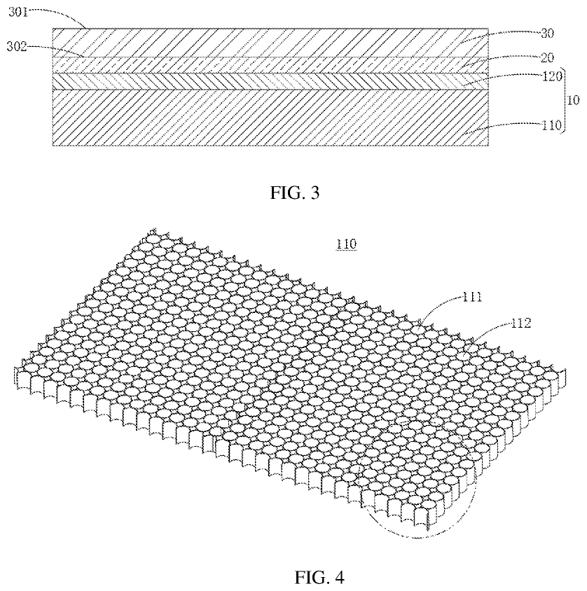

Referring to FIGS. 1-3, FIG. 1 illustrates a schematic structural view of a cover plate assembly in accordance with one embodiment of the present disclosure; FIG. 2 illustrates an exploded view of the cover plate assembly in FIG. 1; FIG. 3 illustrates a cross-sectional view of the cover plate assembly in FIG. 1. The cover plate assembly 1 provided by the present embodiment includes: a photovoltaic panel 30, a bonding layer 20 and a cover plate 10. The photovoltaic panel 30 includes a light absorbing surface 301 and a backlight surface 302 opposite to the light absorbing surface 301. The bonding layer 20 is bonded to the backlight surface 302. The cover plate 10 is bonded to one side of the bonding layer 20 away from the photovoltaic panel 30. The cover plate 10 includes a supporting layer 110 and a reinforcement layer 120. The reinforcement layer 120 is located on at least one side of the supporting layer 110. The supporting layer 110 includes a plastic supporting layer 110 or an aluminum alloy supporting layer 110.

The cover plate assembly 1 is a structure for covering other parts and can be configured to cover other parts. For example, the cover plate assembly 1 can be applied to a tail box 82 of a mobile device 3, such as a truck, a van, a pickup truck, etc., and be configured to cover an opening of the tail box 82, to improve a waterproof and dustproof performance of the tail box 82, and also to improve a security of the tail box 82, to prevent the theft of the cargoes of the tail box 82.

The cover plate assembly 1 mainly includes the photovoltaic panel 30, the bonding layer 20 and the cover plate 10. The bonding layer 20 is bonded between the photovoltaic panel 30 and the cover plate 10. In other words, the photovoltaic panel 30 is bonded to the cover plate 10 by the bonding layer 20. Optionally, the bonding layer 20 includes, but is not limited to, a polyethylene terephthalate (PET) adhesive, an epoxy resin adhesive, a ketoprofen (KPF) liposomal gel, and the like. Furthermore, optionally, the bonding layer 20 may be selected from the KPF adhesive, so as to further improve a flatness of a surface of the bonding layer 20, so as to better bond together with the cover plate 10, and improve the bonding performance.

The cover plate 10 is mainly configured to support the photovoltaic panel 30, which plays a role of supporting and fixing the photovoltaic panel 30. The photovoltaic panel 30 can also be called a solar panel, which is mainly configured for absorbing natural light, unnatural light, and other light, and converting the light energy into electric energy for power supply to other power consumption devices. Therefore, the photovoltaic panel 30 includes the light absorbing surface 301 that absorbs light, and the backlight surface 302 that is opposite to the light absorbing surface 301. The above can also be understood as one side of the bonding layer 20 is bonded to the backlight surface 302, and the other side of the bonding layer 20 is bonded to the cover plate 10. Compared to the conventional cover plate 10, the present disclosure integrates the photovoltaic panel 30 on the cover plate 10, which achieves to cover the opening of the tail box 201 while at the same time utilizing the photovoltaic panel 30 in the cover plate assembly 1 to convert the light energy into electrical energy, thereby providing electrical energy to the power consumption device.

The cover plate 10 mainly includes the supporting layer 110 and the reinforcement layer 120. The supporting layer 110 is mainly used to support the photovoltaic panel 30. The material of the supporting layer 110 is mainly plastic, and optionally the material of the plastic includes but is not limited to polyethylene (PP). As is known from the background, the supporting structure currently used to support the photovoltaic panel 30 is a supporting member made of ferroalloy alloy or ferroalloy profile, which results in excess weight of the product, high manufacturing costs, not conducive to the transportation and installation of the product, and not insulated so it absorb heat easily. Under the same size and volume, the present disclosure uses the plastic supporting layer 110 or the aluminum alloy supporting layer 110 to reduce the weight of the cover plate 10, to realize a light weight of the product, to reduce the manufacturing, installation and transportation costs, and have good thermal insulation without absorbing heat. And supporting layer 110 made of polypropylene is corrosion-resistant, has a long service life, and can be recycled and reused without causing pollution to the environment.

In addition, the reinforcement layer 120 serves as a reinforcement, and the reinforcement layer 120 in conjunction with the supporting layer 110 improves the structural strength of the cover plate 10, so as to well support the cover plate 10. Optionally, the number of the reinforcement layers 120 may be one and be located on one side of the supporting layer 110, for example the reinforcement layer 120 may be located between the supporting layer 110 and the bonding layer 20, or the reinforcement layer 120 may be located on one side of the supporting layer 110 away from the bonding layer 20. Optionally, the number of the reinforcement layers 120 may also be two, the two reinforcement layers 120 are located on opposite sides of the supporting layer 110, and one of the two reinforcement layers 120 is located between the supporting layer 110 and the bonding layer 20, and the other of the two reinforcement layers 120 is located on one side of the supporting layer 110 away from the bonding layer 20.

Furthermore, optionally, the material of the reinforcement layer 120 includes, but is not limited to, fiberglass reinforced plastic (FRP), glass fiber reinforced unsaturated polyester for fiberglass reinforcement, epoxy and phenolic resin matrices, reinforced plastics with glass fibers or their products as reinforcing materials, which is called as fiberglass reinforced plastic, or FRP. The reinforcement layer 120 with fiberglass reinforced plastic material combined with the photovoltaic panel 30 can provide high impact and compression resistance, as well as excellent thermal insulation.

In summary, under a premise of supporting the photovoltaic panel 30, the cover plate 10 provided by the present disclosure can further reduce the product weight of a component of the photovoltaic panel 30 so as to realize a light weight of product, reducing manufacturing, installation and transportation costs, and having good thermal insulation without absorbing heat. Moreover, the composite cover plate 10 has excellent waterproof performance, improves the adhesion between the cover plate 10 and the photovoltaic panel 30, and makes the cover plate 10 and the photovoltaic panel 30 not easy to delaminate. In addition, the cover plate 10 can be processed by cutting and thermoforming processes, which is convenient for processing and more convenient for maintenance and repair at a later stage.

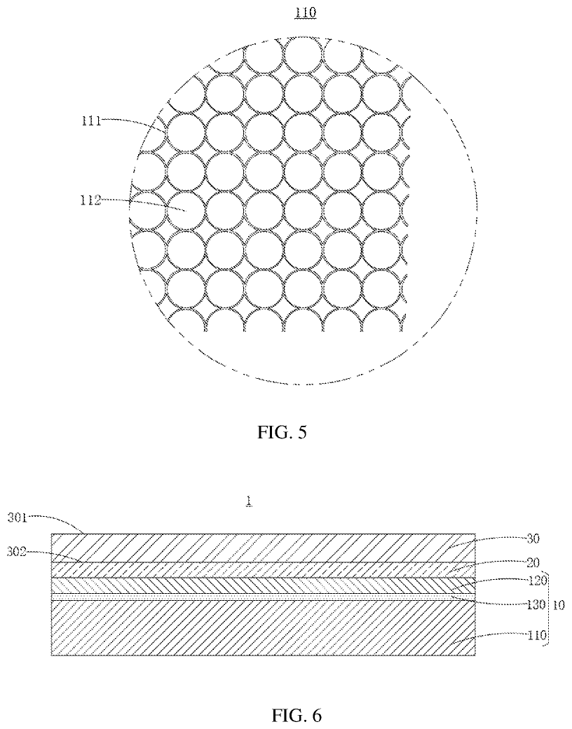

Referring to FIGS. 4 and 5, FIG. 4 illustrates a schematic structural view of a supporting layer in accordance with a second embodiment of the present disclosure; FIG. 5 illustrates a partial top view of the supporting layer in FIG. 4. In this embodiment, the supporting layer 110 includes a plurality of annular supporting portions 111 connected with each other; each annular supporting portion 111 defines a through hole 112 penetrating along a direction from the light absorbing surface 301 to the backlight surface 302, and the aperture of the through hole 112 is 5 mm to 15 mm.

The supporting layer 110 is not a solid layer structure, but is a supporting structure formed by interconnecting and splicing a plurality of annular supporting portions 111. Each annular supporting portion 1111 defines a through hole 112 penetrating along a direction from the light absorbing surface 301 to the backlight surface 302, at which time the supporting layer 110 can be called a PP honeycomb core. As can be seen, the weight of the supporting layer 110 and the cover plate 10 can be further reduced by using the annular supporting portions 1111 to support the photovoltaic panel 30.

In addition, the aperture of the through hole 112 may be 5 mm to 15 mm. If the aperture of the through hole 112 is less than 5 mm, the supporting layer 110 will have a larger weight, which will not be able to satisfy the requirement of light weight of the cover plate assembly 1. If the aperture of the through hole 112 is larger than 15 mm, the aperture is too large, which reduces the structural strength of the supporting layer 110 and fails to meet the requirements for supporting the photovoltaic panel 30. Optionally, the hole diameter of the through hole 112 may be 5 mm, 6 mm, 7 mm, 8 mm, 9 mm, 10 mm, 11 mm, 12 mm, 13 mm, 14 mm, 15 mm.

Referring to FIG. 6, FIG. 6 illustrates a cross-sectional view of the cover plate assembly in accordance with a third embodiment of the present disclosure. The cover plate 10 further includes a heat insulation layer 130 located between the supporting layer 110 and the reinforcement layer 120. The addition of the heat insulation layer 130 between the supporting layer 110 and the reinforcement layer 120 further improves the heat insulation properties of the cover plate 10 and makes it less prone to absorbing heat. The heat insulation layer 130 is made of materials including, but not limited to, polyethylene terephthalate (PET). Furthermore, optionally, the heat insulation layer 130 includes, but is not limited to, a non-woven fabric. Optionally, the number of the heat insulation layer 130 may also be one or two. When the number of the heat insulation layers 130 is one, the heat insulation layer 130 may be located on one side of the supporting layer 110 close to the photovoltaic panel 30, or may be located on one side of the supporting layer 110 away from the photovoltaic panel 30. When the number of heat insulation layers 130 is two, the two heat insulation layers 130 may be located on opposite sides of the supporting layer 110.

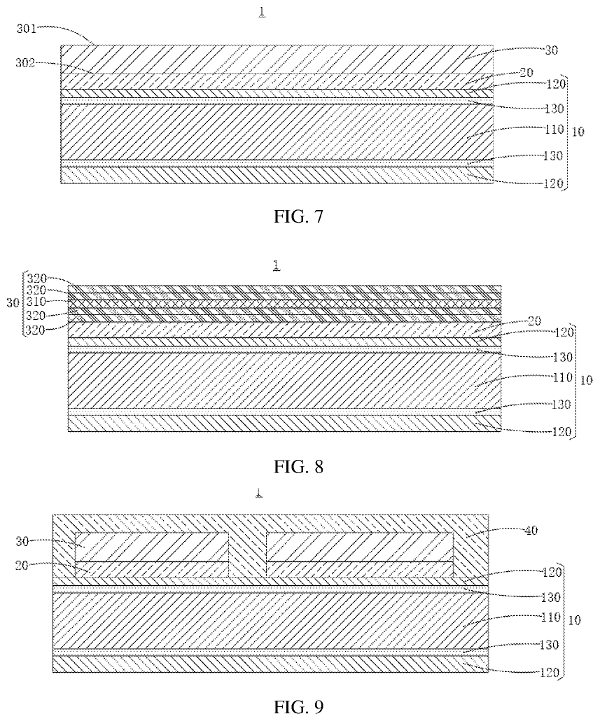

Referring to FIGS. 2 and 7, FIG. 7 illustrates a cross-sectional view of the cover plate assembly in accordance with a fourth embodiment of the present disclosure. In this embodiment, the number of the reinforcement layers 120 and the number of the heat insulation layers 130 are both two. The two the reinforcement layers 120 are located on opposite sides of the supporting layer 110, and each heat insulation layer 130 is located between the supporting layer 110 and the reinforcement layer 120.

In this embodiment, the number of the reinforcement layers 120 and the number of the heat insulation layers 130 are both two; the two the reinforcement layers 120 are located on opposite sides of the supporting layer 110, and each heat insulation layer 130 is located between the supporting layer 110 and the reinforcement layer 120. In other words, in a direction from the light absorbing surface 301 to the backlight surface 302 of the photovoltaic panel 30, the cover plate 10 is stacked with the reinforcement layer 120, the heat insulation layer 130, the supporting layer 110, the heat insulation layer 130, and the reinforcement layer 120, in a sequential order. The strength and heat insulation properties of the plastic can be further improved by setting the reinforcement layer 120 and the heat insulation layer 130 on opposite sides of the supporting layer 110.

Referring again to FIG. 7, in this embodiment, the thickness of the reinforcement layer 120 which is close to the photovoltaic panel 30 is less than the thickness of the reinforcement layer 120 which is away from the photovoltaic panel 30. The present embodiment may enable different thicknesses of the reinforcement layer 120 located on opposite sides of the supporting layer 110 to achieve a differentiated setup. Specifically the thickness of the reinforcement layer 120 which is close to the photovoltaic panel 30 may be made smaller than the thickness of the reinforcement layer 120 which is away from the photovoltaic panel 30, in other word, the thickness of the reinforcement layer 120 bonded to the bonding layer 20 is thinner, and the thickness of the lower reinforcement layer 120 is thicker, so that the lower reinforcement layer 120 can be utilized mainly to improve the structural strength of the cover plate 10, and the upper reinforcement layer 120 can be used to reduce the overall thickness of the cover plate 10, realizing the thinning of the cover plate assembly 1.

Optionally, the thickness of the reinforcement layer 120 which is close to the photovoltaic panel 30 is 0.1 mm-0.5 mm, and the thickness of the reinforcement layer 120 which is away from the photovoltaic panel 30 is 0.5 mm-1.5 mm. Furthermore, optionally, the thickness of the reinforcement layer 120 which is close to the photovoltaic panel 30 is 0.1 mm, 0.2 mm, 0.3 mm, 0.4 mm, 0.5 mm. The thickness of the reinforcement layer 120 which is away from the photovoltaic panel 30 is 0.5 mm, 0.6 mm, 0.7 mm, 0.8 mm, 0.9 mm, 1.0 mm, 1.1 mm, 1.2 mm, 1.3 mm, 1.4 mm, 1.5 mm.

In this embodiment, the thickness of the supporting layer 110 is 7 mm-15 mm. Optionally, the thickness of the supporting layer 110 is 7 mm, 8 mm, 9 mm, 10 mm, 11 mm, 12 mm, 13 mm, 14 mm, 15 mm.

In this embodiment, the thickness of the heat insulation layer 130 is 0.05 mm-0.15 mm. Optionally, the thickness of the heat insulation layer 130 is 0.05 mm, 0.06 mm, 0.07 mm, 0.08 mm, 0.09 mm, 0.1 mm, 0.11 mm, 0.12 mm, 0.13 mm, 0.13 mm, 0.14 mm, 0.15 mm, 0.13 mm, 0.14 mm, 0.15 mm.

In this embodiment, the total thickness of the cover plate 10 is 7.7 mm-17.15 mm, Specifically, the total thickness of the cover plate 10 is a sum of the thicknesses of each of the above layers. By controlling the thicknesses of different layers, the total thickness of the cover plate 10 can be controlled. Optionally, the total thickness of the cover plate 10 is 7.7 mm, 8 mm, 8.5 mm, 9 mm, 9.5 mm, 10 mm, 10.5 mm, 11 mm, 11.5 mm, 12 mm, 12.5 mm, 13 mm, 13.5 mm, 14 mm, 14.5 mm, 15 mm, 15.5 mm, 16 mm, 16.5 mm, 17 mm, 17.15 mm.

In this embodiment, the thickness of the photovoltaic panel 30 is 2 mm-2.5 mm. Optionally, the thickness of the photovoltaic panel 30 is 2 mm, 2.1 mm, 2.2 mm, 2.3 mm, 2.4 mm, 2.5 mm.

Referring to FIG. 8, FIG. 8 illustrates a cross-sectional view of the cover plate assembly in accordance with a fifth embodiment of the present disclosure. In this embodiment, the photovoltaic panel 30 includes a battery sheet 310 and four layers of hot melt adhesive layers 320 (EVA) located on opposite sides of the battery sheet 310. The hot melt adhesive layers 320 can protect a center of the battery sheet 310. Two layers of the hot melt adhesive layers 124 are located on one side of the battery sheet 310 away from the cover plate 10, and another two layers of the hot melt adhesive layers 124 are located on one side of the battery sheet 310 close to the cover plate 10. As for the specific structure of the photovoltaic panel 30, the present disclosure is not limited herein.

In this embodiment, the thickness of the cover plate assembly 1 is 10 mm-20 mm. Optionally, the thickness of the cover plate assembly 1 is 10 mm, 11 mm, 12 mm, 13 mm, 14 mm, 15 mm, 16 mm, 17 mm, 18 mm, 19 mm, 20 mm.

Referring to FIG. 9, FIG. 9 illustrates a cross-sectional view of the cover plate assembly in accordance with a sixth embodiment of the present disclosure. In this embodiment, the number of the photovoltaic panels 12 is multiple. Multiple photovoltaic panels 12 are bonded to the cover plate 10 in an array by the bonding layer 13. The cover plate assembly 1 further includes a flat layer 40. The flat layer 40 is located on the cover plate 10 where the photovoltaic panel 30 is not set, and on the photovoltaic panel 30. A surface of the flat layer 40 away from the cover plate 10 is flush.

The number of photovoltaic panels 12 may be multiple, and multiple photovoltaic panels 12 are located in an array on the cover plate 10. In other words, each photovoltaic panel 30 is bonded to the cover plate 10 by the bonding layer 20. The foregoing can also be understood to mean that the cover plate 10 is not provided with a whole layer of the photovoltaic panel 30, but consists of a plurality of photovoltaic panels 30 arranged in an array. The cover plate assembly 1 may include, in addition to the above-described components, the flat layer 40, which is located at an area of the cover plate 10 where the photovoltaic panel 30 is not set, and a side of the photovoltaic panel 30 away from the cover plate 10, so as to play a role of covering and protecting the photovoltaic panel 30. Optionally, the flat layer 40 has light transmittance, and the light can be directed to the photovoltaic panel 30 through the flat layer 40. Moreover, a surface of the flat layer 40 away from the cover plate 10 is flush, i.e., the top surface of the flat layer 40 is set flush, which can improve a flatness of the cover plate assembly 1. Optionally, the material of the flat layer 40 includes, but is not limited to, an Ethylene-tetrafluoroethylene copolymer, and the use of the above material makes the flat layer 40 have characteristics such as heat resistance, abrasion resistance, and scratch resistance.

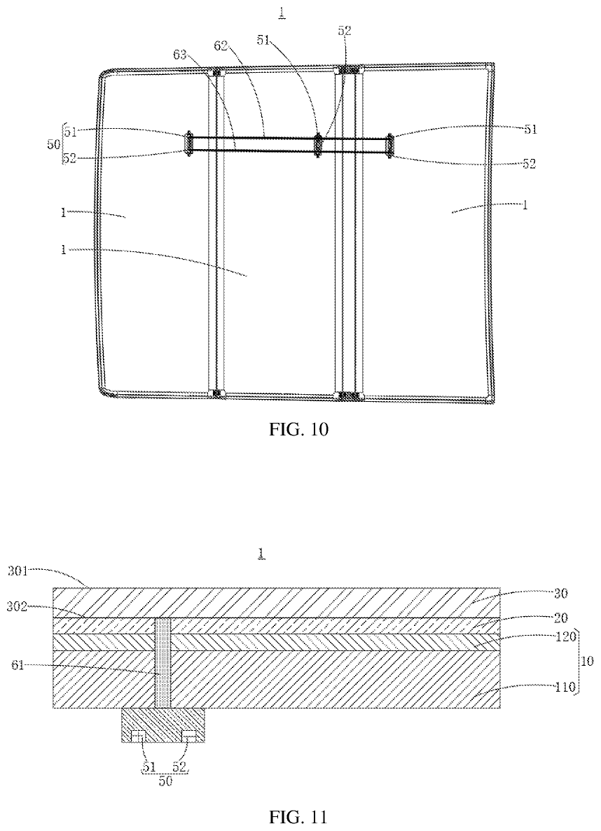

Referring to FIGS. 10 and 11, FIG. 10 illustrates a top view of the cover plate assembly in accordance with another embodiment of the present disclosure from another view; FIG. 11 illustrates a cross-sectional view of the cover plate assembly in accordance with a seventh embodiment of the present disclosure. In this embodiment, the cover plate assembly 1 further includes a first electrically conductive member 61 and a connector 50. The connector 50 is fixed to one side of the cover plate 10 that is away from the photovoltaic panel 30 and directly faces the photovoltaic panel 30. One end of the first electrically conductive member 61 is electrically connected to the photovoltaic panel 30, and the other end of the first electrically conductive member 61 passes through the bonding layer 20 and the cover plate 10, so as to electrically connected to the connector 50.

The cover plate assembly 1 may also include the first electrically conductive member 61 and the connector 50, therein, the connector 50 is fixed to one side of the cover plate 10 away from the photovoltaic panel 30, i.e., the photovoltaic panel 30 is set above the cover plate 10, and the connector 50 is set below the cover plate 10. The connector 50 directly faces the photovoltaic panel 30 to facilitate connection of the first electrically conductive member 61. One end of the first conductive member 61 is electrically connected to the photovoltaic panel 30, and the other end of the first conductive member 61 passes through the bonding layer 20 and the cover plate 10, so as to electrically connect the connector 50, whereby the first conductive member 61 can be utilized to transmit the converted electrical energy of the photovoltaic panel 30 to the connector 50 through the first conductive member 61, and then subsequently transmitted by the connector 50 to an energy storage device or a power consumption device. Optionally, the first conductive member 61 includes, but is not limited to, a wire.

Referring to FIGS. 10 and 11, in this embodiment, the number of the cover plate assemblies 1 is multiple, and multiple cover plate assemblies 1 are rotationally connected in sequence along a predetermined direction, the connectors 50 of the plurality of the cover plate assemblies 1 are also arranged along the predetermined direction. The connector 50 includes a positive terminal 51 and a negative terminal 52. When the plurality of the cover plate assemblies 1 are flattened, the positive terminal 51 of each connector 50 directly corresponds to the positive terminals 51 of the other connectors 50, and the negative terminal 52 of each connector 50 directly corresponds to the negative terminals 52 of the other connectors 50.

The number of the cover plate assemblies 1 may be multiple, and the present embodiment is illustrated schematically with only three cover plate assemblies 1. Each cover plate assembly 1 is in a shape of a rectangle, and the three cover plate assemblies 1 are sequentially arranged along a width direction of the rectangle, and two adjacent cover plate assemblies 1 are rotationally connected. Specifically, the first cover plate assembly 1 is rotationally connected to one end of the second cover plate assembly 1, and the other end of the second cover plate assembly 1 is rotationally connected to the third cover plate assembly 1. The three cover plate assemblies 1 can be folded two times, thereby changing an overall size of the three cover plate assemblies 1.

Each cover plate assembly 1 includes one first electrical connecting member 61 and one connector 50. In this embodiment, the three connectors 50 are also arranged along the predetermined direction, i.e., the width direction. Each connector 50 includes the positive terminal 51 and the negative terminal 52. The present embodiment enables the plurality of the cover plate assemblies 1 to be flattened, and the positive terminal 51 of each connector 50 directly corresponds to the positive terminals 51 of the other connectors 50, and the negative terminal 52 of each connector 50 directly corresponds to the negative terminals 52 of the other connectors 50. In other words, the positive terminal 51 corresponds to the other positive terminals 51 and the negative terminal 52 corresponds to the other negative terminals 52, which facilitates the connection of subsequent electrical connecting members.

Referring to FIG. 11, in this embodiment, the cover plate assembly 1 further includes at least one second electrical connecting member 62 and at least one third electrical connecting member 63. Opposite ends of each second electrical connecting member 62 are electrically connected to positive connectors 151 of two adjacent connectors 15. Opposite ends of each third electrical connecting member 63 are electrically connected to negative connectors 152 of the two adjacent connectors 15. The second electrical connecting member 62 and the third electrical connecting member 63 are removably connected to the connector 50, and/or the length of the second electrical connecting member 62 and the third electrical connecting member 63 is capable of being elongated and is capable of being restored to its original shape.

The cover plate assembly 1 can further includes the second electrical connecting member 62 and the third electrical connecting member 63, the second electrical connecting member 62 is configured to electrically connect the positive connectors 151 of the two adjacent connectors 15, and the third electrical connecting member 63 is configured to electrically connect the negative connectors 152 of the two adjacent connectors 15, thereby connecting the positive connectors 151 and the negative connectors 152 of the multiple cover plate assembly 1 together, which can simplify the layout of the electrical connectors and facilitate subsequent electrical connection to the energy storage device or the power consumption device.

Moreover, since the cover plate assemblies 1 will rotate with each other for being folded two times, it is possible in one embodiment to make the second electrical connecting member 62 and the third electrical connecting member 63 removably connected to the connectors 50, i.e. the second electrical connecting member 62 and the third electrical connecting member 63 are disassembled from the connectors 50 when folded, and the second electrical connecting member 62 and the third electrical connecting member 63 are assembled to the connectors 50 when flattened, avoiding the second electrical connecting member 62 and the third electrical connecting member 63 from affecting the folding of the cover plate assemblies 1. In another embodiment, the length of the second electrical connecting member 62 and the third electrical connecting member 63 is variable, so that the length can be elongated when folded, and returned to its original length when flattened, so as not to affect the folding of the cover plate assembly 1. Optionally, the second electrical connecting member 62 and the third electrical connecting member 63 include, but are not limited to, threaded wires.

It should be noted that, the present embodiment may satisfy only one embodiment or another embodiment, or both one embodiment and another embodiment.

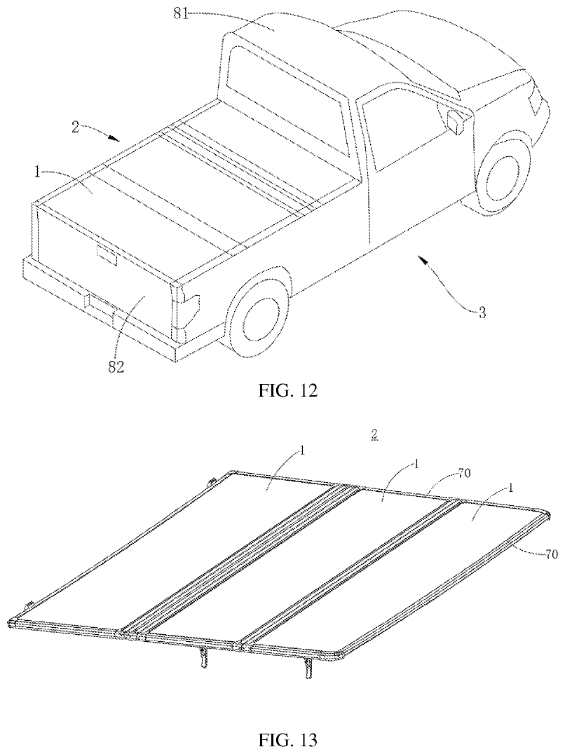

Referring to FIGS. 12-17, FIG. 12 illustrates a schematic view of a fit of the foldable cover plate applied to a mobile device in accordance with one embodiment of the present disclosure;

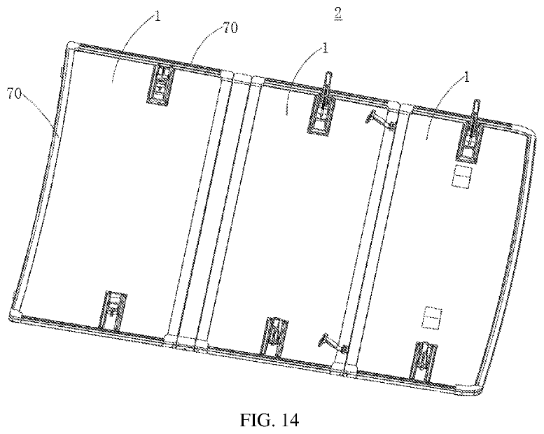

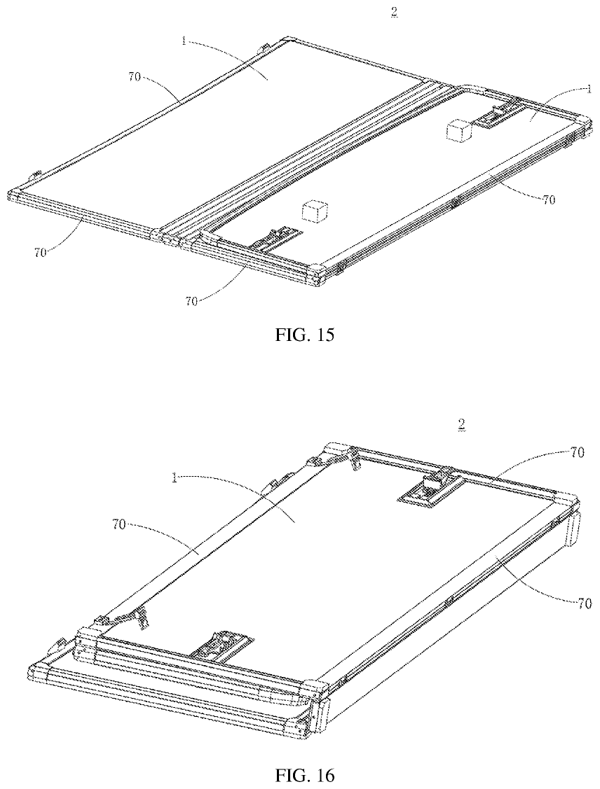

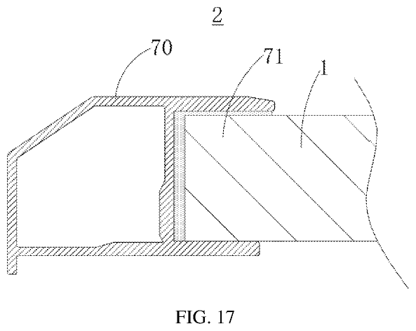

FIG. 13 illustrates a schematic structural view of the foldable cover plate in accordance with one embodiment of the present disclosure; FIG. 14 illustrates a schematic structural view of the foldable cover plate in FIG. 13 from another view; FIG. 15 illustrates a schematic structural view of the foldable cover plate of FIG. 13 after being folded first time; FIG. 16 illustrates a schematic structural view of the foldable cover plate of FIG. 13 after being folded second time; FIG. 17 illustrates a partial cross-sectional view of the foldable cover plate of FIG. 13. The present embodiment provides a foldable cover plate 2 for mounting to a tail box 82 of a mobile device 3 to cover an opening of the tail box 82. The foldable cover plate 2 includes a plurality of rotatably connected cover plate assemblies 1, and a profile 70. The cover plate assembly 1 is rotatably foldable onto the remaining cover plate assemblies 1 to expose the opening. The profile 70 defines a receiving groove. 71. The cover plate assembly 1 having a peripheral edge bonded to a groove wall of the receiving groove 71.

The mobile device 3 includes, but is not limited to, vehicles having an open tail box 82 such as pickup trucks, trucks, box vans, snowmobiles, etc. The foldable cover plate 2 may be mounted on a box frame of the tail box 82 to cover the opening of the tail box 82 when the foldable cover plate 2 is flattened, thereby effectively protecting the opening of the tail box 82. The foldable cover plate 2 includes a plurality of cover plate assemblies 1 provided in the above embodiment rotationally connected in sequence, and the profile 70. The cover plate assembly 1 can be folded to other cover plate assemblies 1 to varying degrees when folded to other cover plate assemblies 1, and the user may fold the cover plate assembly 1 according to the needs of the user. For example, in the present embodiment, the foldable cover plate 2 is schematically illustrated as including three cover plate assemblies 1. The cover plate assembly 1 located at a tail portion of the tail box 82 can be rotated to lap onto the cover plate assembly 1 located in a center of the tail box 82 to expose a portion of the opening of the tail box 82 for easy access to cargoes. Furthermore, the cover plate assembly 1 in the center of the tail box 82 can be rotated again so that the cover plate assembly 1 in the center of the tail box 82 and the cover plate assembly 1 at the tail portion of the tail box 82 can be lapped together onto the cover plate assembly 1 close to the driver's cab 81 to expose more of the opening of the tail box 82 to facilitate access to larger cargoes. And the profile 70 defines a receiving groove 71 for receiving the peripheral edge of the cover plate assembly 1. In other words, the peripheral edge of the cover plate assembly 1 may be bonded to the groove wall of the receiving groove 71 by a sealant and subsequently secured using screw fasteners. Optionally, the installation may be performed by heat fusion welding with riveting.

Optionally, the tail box 82 is provided with an energy storage device, which is electrically connected to the photovoltaic panels 30 of the cover plate assemblies 1 in the foldable cover plate 2, and transmits the converted electrical energy of the photovoltaic panels 30 to the energy storage device for reserve. Alternatively, the photovoltaic panel 30 may be directly electrically connected to an electrical device within the mobile device 3 or to a battery within the mobile device 3 to provide electrical energy or to recharge it.

The foldable cover plate 2 provided in the present embodiment, by adopting the cover plate assembly 1 provided in the above embodiment of the present disclosure, not only covers the opening of the tail box 82, but also utilizes the photovoltaic panel 30 in the cover plate assembly 1 to convert light energy into electrical energy, thereby providing electrical energy for the mobile device 3, thereby providing electrical energy for the mobile device 3.

In this embodiment, the peripheral edge of the cover plate 10 of the cover plate assembly 1 is located within the receiving groove 71, and the photovoltaic panel 30 of the cover plate assembly 1 is located outside the receiving groove 71. When the peripheral edge of the cover plate assembly 1 is set inside the receiving groove 71, the present embodiment allows the photovoltaic panel 30 of the cover plate assembly 1 to be set outside the receiving groove 71, in other words, the cover plate 10 is not provided with a photovoltaic panel 30 at the peripheral edge of the cover plate 10, which not only improves the utilization rate of the photovoltaic panel 30, but also effectively protects the photovoltaic panel 30 and prevents the photovoltaic panel 30 from being damaged.

In this embodiment, when the cover plate assembly 1 is folded, one profile 70 of one cover plate assembly 1 is pressed onto one profile 70 of the other cover plate assembly 1 to avoid the photovoltaic panel 30 of the cover plate assembly 1 from being crushed by the profile 70, effectively protecting the photovoltaic panel 30.

In the description of this application, it is to be understood that the terms “center”, “longitudinal”, “orthogonal”, “length”, “width”, “thickness”, “top”, “bottom”, “front”, “back”, “left”, “right”, “vertical”, “horizontal”, “top”, “bottom”, “inside”, “outside,” “clockwise,” “counterclockwise”, and the like indicate orientation or positional relationships based on those shown in the accompanying drawings, and are intended only to facilitate the description of the present disclosure and to simplify the description

Furthermore, the terms “first” and “second” are used only for descriptive purposes, and are not to be construed as indicating or implying relative importance or implicitly specifying the number of technical features indicated. Thus, a feature defined with “first” or “second” may include one or more such features, either explicitly or implicitly. In the description of the present disclosure, “more than one” means two or more, unless otherwise expressly and specifically limited. In addition, the terms “including” and “having”, and any variations thereof, are intended to cover non-exclusive inclusion.

For the purposes of this application, unless otherwise expressly specified and limited, the terms “mounted,” “connected,” “connected,” “fixed,” and the like shall be understood broadly, e.g., they may be connected, detachable, or integral. It can be mechanically connected or electrically connected. It can be a direct connection or an indirect connection through an intermediate medium, a connection within two elements or an interactive relationship between two elements. For those of ordinary skill in the art, the specific meanings of the above terms in the present disclosure may be understood on a case-by-case basis.

The above detailed description of the contents provided in the embodiments of the present disclosure and the exposition and explanation of the principles and embodiments of the present disclosure are only used to help understand the method of the present disclosure and its core ideas. However, the contents of this specification should not be construed as a limitation of the present disclosure, and the person skilled in the art may make various modifications and variations to the present disclosure without departing from the spirit and scope of the present disclosure. These modifications and variations of the present disclosure are within the scope of the claims of the present disclosure and their technical equivalents.

1. A cover plate assembly, wherein the cover plate assembly comprises:
a photovoltaic panel comprising a light absorbing surface and a back surface opposite to the light absorbing surface;
a bonding layer being bonded to the back surface; and
a cover plate being bonded to one side of the bonding layer away from the photovoltaic panel; wherein the cover plate comprises a supporting layer and a reinforcement layer; the reinforcement layer is located on at least one side of the supporting layer, the supporting layer comprises a supporting layer or an aluminium alloy supporting layer;
the supporting layer comprises a plurality of annular supporting portions connected with each other, each annular supporting portion defines a through hole penetrating along a direction from the light absorbing surface to the back surface, an aperture of the through hole is 5 mm to 15 mm; the thickness of the supporting layer is 7 mm-15 mm;
wherein the cover plate assembly further comprises a first electrical connecting member and a connector, the connector is fixed to one side of the cover plate away from the photovoltaic panel and directly faces the photovoltaic panel, one end of the first electrical connecting member is electrically connected to the photovoltaic panel and the other end of the first electrical connecting member passes through the bonding layer and the cover plate to be electrically connected to the connector;
the number of the cover plate assemblies is multiple, multiple cover plate assemblies are rotationally connected in sequence along a predetermined direction, the connectors of the multiple cover plate assemblies are also arranged along the predetermined direction; the connector comprises a positive terminal and a negative terminal; when the multiple cover plate assemblies are flattened, the positive terminal of each connector directly corresponds to the positive terminals of the other connectors, and the negative terminal of each connector directly corresponds to the negative terminals of the other connectors;
the cover plate assembly further comprises at least one second electrical connecting member and at least one third electrical connecting member; opposite ends of each second electrical connecting member are electrically connected to the positive terminals of the two adjacent connectors; opposite ends of each third electrical connecting member are electrically connected to the negative terminals of the two adjacent connectors;
wherein the second electrical connecting member and the third electrical connecting member are removably connected to the connectors of the multiple cover plate assemblies; when one or more of the multiple cover plate assemblies are rotated and folded to the other of the multiple cover plate assemblies, the second electrical connecting member and the third electrical connecting member are disassembled from the connectors of the multiple cover plate assemblies, when the multiple cover plate assemblies are flattened, the second electrical connecting member and the third electrical connecting member are connected to the connectors of the multiple cover plate assemblies.

2. (canceled)

3. The cover plate assembly according to claim 1, wherein the cover plate further comprises a heat insulation layer located between the supporting layer and the reinforcement layer.

4. The cover plate assembly according to claim 3, wherein the number of the reinforcement layers and the number of the heat insulation layers are both two, the two reinforcement layers are located on opposite sides of the supporting layer, each heat insulation layer is located between the supporting layer and the reinforcement layer.

5. The cover plate assembly according to claim 4, wherein a thickness of the reinforcement layer which close to the photovoltaic panel is less than that of the reinforcement layer which is away from the photovoltaic panel.

6. The cover plate assembly according to claim 1, wherein the number of the photovoltaic panels is multiple, multiple photovoltaic panels are bonded to the cover plate in an array by the bonding layer; the cover plate assembly further comprises a flat layer, the flat layer is located on the cover plate where the photovoltaic panel is not set, and on the photovoltaic panel; a surface of the flat layer away from the cover plate is flush.

7-9. (canceled)

10. A foldable cover plate, wherein, the foldable cover plate is configured for mounting to a tail box of a mobile device to cover an opening of the tail box; the foldable cover plate comprises multiple cover plate assemblies rotationally connected and a profile, wherein the cover plate assembly comprises:
a photovoltaic panel comprising a light absorbing surface and a back surface opposite to the light absorbing surface;
a bonding layer being bonded to the back surface; and
a cover plate being bonded to one side of the bonding layer away from the photovoltaic panel; wherein the cover plate comprises a supporting layer and a reinforcement layer; the reinforcement layer is located on at least one side of the supporting layer; wherein, the supporting layer comprises a supporting layer or an aluminium alloy supporting layer;
wherein the cover plate assembly is rotatably foldable to the remaining cover plate assemblies to expose the opening; the profile defines a receiving groove; a peripheral edge of the cover plate assembly is bonded to a groove wall of the receiving groove;
wherein the supporting layer comprises a plurality of annular supporting portions connected with each other, each annular supporting portion defines a through hole penetrating along a direction from the light absorbing surface to the back surface, an aperture of the through hole is 5 mm to 15 mm; the thickness of the supporting layer is 7 mm-15 mm;
the cover plate assembly further comprises a first electrical connecting member and a connector, the connector is fixed to one side of the cover plate away from the photovoltaic panel and directly faces the photovoltaic panel, one end of the first electrical connecting member is electrically connected to the photovoltaic panel and the other end of the first electrical connecting member passes through the bonding layer and the cover plate to be electrically connected to the connector;
wherein the multiple cover plate assemblies are rotationally connected in sequence along a predetermined direction, the connectors of the multiple cover plate assemblies are also arranged along the predetermined direction; the connector comprises a positive terminal and a negative terminal; when the multiple cover plate assemblies are flattened, the positive terminal of each connector directly corresponds to the positive terminals of the other connectors, and the negative terminal of each connector directly corresponds to the negative terminals of the other connectors;
wherein the cover plate assembly further comprises at least one second electrical connecting member and at least one third electrical connecting member; opposite ends of each second electrical connecting member are electrically connected to the positive terminals of the two adjacent connectors; opposite ends of each third electrical connecting member are electrically connected to the negative terminals of the two adjacent connectors;
wherein the second electrical connecting member and the third electrical connecting member are removably connected to the connectors of the multiple cover plate assemblies; when one or more of the multiple cover plate assemblies are rotated and folded to the other of the multiple cover plate assemblies, the second electrical connecting member and the third electrical connecting member are removed from the connectors of the multiple cover plate assemblies, when the multiple cover plate assemblies are flattened, the second electrical connecting member and the third electrical connecting member are connected to the connectors of the multiple cover plate assemblies.

11. The foldable cover plate according to claim 10, wherein the cover plate assembly comprises:
a photovoltaic panel comprising a light absorbing surface and a back surface opposite to the light absorbing surface;
a bonding layer being bonded to the back surface; and
a cover plate being bonded to one side of the bonding layer away from the photovoltaic panel; wherein the cover plate comprises a supporting layer and a reinforcement layer; the reinforcement layer is located on at least one side of the supporting layer.

12. (canceled)

13. The foldable cover plate according to claim 10, wherein the cover plate further comprises a heat insulation layer located between the supporting layer and the reinforcement layer.

14. The foldable cover plate according to claim 13, wherein the number of the reinforcement layers and the number of the heat insulation layers are both two, the two reinforcement layers are located on opposite sides of the supporting layer, each heat insulation layer is located between the supporting layer and the reinforcement layer.

15. The foldable cover plate according to claim 14, wherein a thickness of the reinforcement layer which close to the photovoltaic panel is less than that of the reinforcement layer which is away from the photovoltaic panel.

16. The foldable cover plate according to claim 10, wherein the number of the photovoltaic panels is multiple, multiple photovoltaic panels are bonded to the cover plate in an array by the bonding layer; the cover plate assembly further comprises a flat layer, the flat layer is located on the cover plate where the photovoltaic panel is not set, and on the photovoltaic panel; a surface of the flat layer away from the cover plate is flush.

17-19. (canceled)

20. A cover plate assembly, wherein the cover plate assembly comprises:
a photovoltaic panel comprising a light absorbing surface and a back surface opposite to the light absorbing surface;
a bonding layer being bonded to the back surface; and
a cover plate being bonded to one side of the bonding layer away from the photovoltaic panel; wherein the cover plate comprises a supporting layer and a reinforcement layer; the reinforcement layer is located on at least one side of the supporting layer, the supporting layer comprises a supporting layer or an aluminium alloy supporting layer;
wherein the cover plate assembly further comprises a first electrical connecting member and a connector, the connector is fixed to one side of the cover plate away from the photovoltaic panel and directly faces the photovoltaic panel, one end of the first electrical connecting member is electrically connected to the photovoltaic panel and the other end of the first electrical connecting member penetrates through the bonding layer and the cover plate to be electrically connected to the connector;
wherein the number of the cover plate assemblies is multiple, multiple cover plate assemblies are rotationally connected in sequence along a predetermined direction, the connectors of the multiple cover plate assemblies are also arranged along the predetermined direction; the connector comprises a positive terminal and a negative terminal; when the multiple cover plate assemblies are flattened, the positive terminal of each connector directly corresponds to the positive terminals of the other connectors, and the negative terminal of each connector directly corresponds to the negative terminals of the other connectors;
wherein the cover plate assembly further comprises at least one second electrical connecting member and at least one third electrical connecting member; opposite ends of each second electrical connecting member are electrically connected to the positive terminals of the two adjacent connectors; opposite ends of each third electrical connecting member are electrically connected to the negative terminals of the two adjacent connectors;
wherein the second electrical connecting member and the third electrical connecting member are removably connected to the connectors of the multiple cover plate assemblies; when one or more of the multiple cover plate assemblies are rotated and folded to the other of the multiple cover plate assemblies, the second electrical connecting member and the third electrical connecting member are removed from the connectors of the multiple cover plate assemblies, when the multiple cover plate assemblies are flattened, the second electrical connecting member and the third electrical connecting member are connected to the connectors of the multiple cover plate assemblies.

21. (canceled)
